(19) United States
(12) Patent Application Publication
(10) Pub. No.: US 2025/0336804 A1
(43) Pub. Date: Oct. 30, 2025

(54) WIRING METHOD FOR SEMICONDUCTOR CIRCUIT DEVICE, WIRING PROGRAM AND WIRING PROCESSING DEVICE

(71) Applicant: Renesas Electronics Corporation, Tokyo (JP)

(72) Inventor: Nobuhiro YADA, Tokyo (JP)

(21) Appl. No.: 19/073,529

(22) Filed: Mar. 7, 2025

(30) Foreign Application Priority Data
Apr. 24, 2024 (JP) 2024-070753

(51) Int. Cl. H01L 23/522

(52) U.S. Cl. CPC H01L 23/5225

(57) ABSTRACT

A wiring method of the semiconductor circuit device includes arranging a plurality of shield wiring candidates such that the plurality of shield wiring candidates adjacent to each other are arranged apart by a space for a wiring track, arranging a shield target wiring on at least one of wiring tracks between the plurality of shield wiring candidates adjacent to each other, and removing a shield wiring candidate which do not contribute as shield wiring to the shield target wiring arranged.

### CROSS-REFERENCE TO RELATED APPLICATIONS

The disclosure of Japanese Patent Application No. 2024-070753 filed on Apr. 24, 2024, including the specification, drawings and abstract is incorporated herein by reference in its entirety.

### BACKGROUND

The present invention related to a wiring method, a wiring program, and a wiring processing device for a semiconductor circuit device.

In order to prevent crosstalk between adjacent signal nets, a ground net or a power supply net is arranged on both sides of a signal net that interferes with other signal nets or needs to prevent interference from other signal nets and shield the signal net.

There are disclosed techniques listed below.
[Patent Document 1] Japanese Unexamined Patent Application Publication No. 2000-259695

Patent Document 1 discloses an automated wiring technique in which a wiring path of a signal net that needs to be shielded is searched, and when the wiring path of the signal net is determined, a shield net for shielding the signal net is arranged on one or both sides of the signal net with a predetermined clearance provided.

### SUMMARY

In Patent Document 1, when a wiring path of a signal net that needs to be shielded is searched, if there is a power supply net or a ground net that has already been arranged, the wiring path is searched so that the signal net is adjacent to a power supply net or a ground net that has already been arranged (hereinafter, referred to as an already-arranged power supply net or the like) with a predetermined clearance provided. When wiring adjacent to the already-arranged power supply net or the like is successful, the already-arranged power supply net is used as a shield net for shielding the signal net.

However, in Patent Document 1, in order to use the already-arranged power supply net or the like as a shield net, a wiring path is searched so that the signal net to be shielded is drawn to the already-arranged power supply net or the like. As a result, there is a problem that an ideal wiring path cannot be selected.

Other objects and novel features will become apparent from the description of this specification and the accompanying drawings.

A wiring method of the semiconductor circuit device according to one aspect of the present disclosure includes arranging a plurality of shield wiring candidates such that the plurality of shield wiring candidates adjacent to each other are arranged apart by a space for a wiring track, arranging a shield target wiring on at least one of wiring tracks between the plurality of shield wiring candidates adjacent to each other, and removing a shield wiring candidate which do not contribute as shield wiring to the shield target wiring arranged.

A wiring program of a semiconductor circuit device according to another aspect of the present disclosure is stored in a non-transitory computer readable medium and is executable processes by a computer. The processes includes arranging a plurality of shield wiring candidates such that the plurality of shield wiring candidates adjacent to each other are arranged apart by a space for a wiring track, arranging a shield target wiring on at least one of wiring tracks between the plurality of shield wiring candidates adjacent to each other, and removing a shield wiring candidate which do not contribute as shield wiring to the shield target wiring arranged.

A wiring processing device according to still another aspect of the present disclosure includes a shield wiring candidate arrangement unit configured to arrange a plurality of shield wiring candidates such that the plurality of shield wiring candidates adjacent to each other are arranged apart by a space for a wiring track, a shield target arrangement unit configured to arrange a shield target wiring on at least one of wiring tracks between the plurality of shield wiring candidates adjacent to each other, and a removing unit configured to a shield wiring candidate which do not contribute as shield wiring to the shield target wiring arranged.

According to the present disclosure, it is possible to select the wiring path of the shield target wiring without being drawn to the already-arranged wiring.

### BRIEF DESCRIPTION OF THE DRAWINGS

FIG. 1 is a diagram illustrating an exemplary wiring processing device of a semiconductor circuit device according to an embodiment.

FIG. 2 is a diagram illustrating an example of shield wiring candidates.

FIG. 3 is a diagram illustrating a state in which a shield target wiring is wired to a wiring track between shield wiring candidates in FIG. 2.

FIG. 4 is a diagram for explaining a process of removing shield wiring candidates.

FIG. 5 is a diagram for explaining a process of removing shield wiring candidates.

FIG. 6 is a diagram for explaining a process of removing vias between crossing shield wiring candidates.

FIG. 7 is a flowchart illustrating an example of a wiring method of the semiconductor circuit device according to the embodiment.

### DETAILED DESCRIPTION

Form implementation of disclosure will be described below with reference to the drawings. Since the drawings are simplified, the technical scope of the present disclosure should not be construed narrowly on the basis of the description of the drawings. In the drawings, the same elements are denoted by the same reference numerals, and redundant description thereof will be omitted. It should be noted that the drawings are not drawn to scale for convenience of explanation.

In the following embodiments, when necessary for convenience, it will be described by dividing into a plurality of sections or embodiments. However, unless otherwise specified, they are not related to each other, and one is related to some or all of the other modified example, applications, detailed descriptions, supplementary descriptions, and the like. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle.

Furthermore, in the following embodiments, the constituent elements (including the operation steps and the like) are not essential except in the case where they are necessarily specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above-mentioned numbers and the like, including the number, the numerical value, the amount, the range, and the like.

The present disclosure relates to a wiring method, a wiring program, and a wiring processing device for automatically wiring shield wirings for shielding shield target wirings on a semiconductor chip or a printed circuit board in order to manufacture a semiconductor circuit device including shield wirings for shielding the shield target wirings.

The shield target wiring is a signal wiring that interferes with other signal wiring or a signal wiring that needs to be prevented from interfering with another signal wiring. The shield target wiring may be a clock wiring through which a high-frequency signal passes, or data wiring through which a high-speed data signal (e.g., an analog signal of high-speed SerDes (SERializer/DESerializer) interface circuit) or a sensitive analog signal (e.g., a VDD sense signal for temperature measurement or potential measurement, ADC analog signal, etc.), and the like passes. The shield wiring is arranged on both sides of the signal wiring and prevents crosstalk between adjacent signal wirings.

In the advanced process, the wiring pitch becomes narrower with miniaturization and densification of the semiconductor element. In addition, voltage scaling is adopted from the viewpoint of reliability and power consumption of the semiconductor device. Thus, the noise sensitivity of the signal wiring is increased, and fine shield wirings are to be provided.

Normally, wiring resources for the shield wiring are provided on both sides of each shield target wiring. However, the shield wiring is not necessarily arranged on both sides of each shield target wiring and may be omitted. For example, in a case where the wiring pitch is narrow, it is conceivable that the shield wiring is shared by adjacent shield target wirings.

However, in a case where the shield wiring is arranged after many shield target wirings are freely wired, the shield wiring cannot be made common, redundant shield wirings are generated, and wiring congestion may be caused. In order to reduce the chip size, it is necessary to prevent wiring congestion due to the shield wiring.

On the other hand, when the already-arranged power supply net or already-arranged ground net is used as the shield wiring as disclosed in Patent Document 1 described above, the unnecessary shield wirings can be eliminated. However, the shield wirings are arranged to be drawn to the already-arranged wirings. In particular, since the clock wirings affect the timing and power of the semiconductor circuit device, it is necessary to ensure the quality of the clock wiring including the shield wiring.

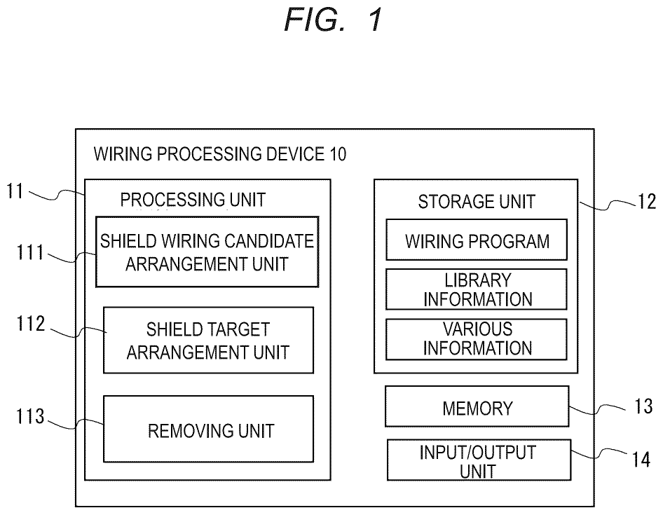

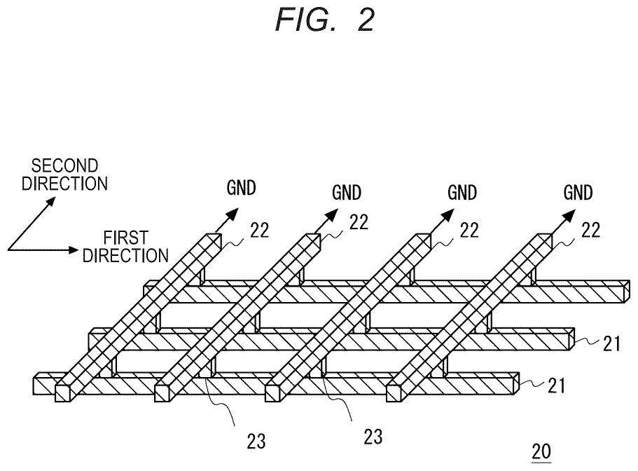

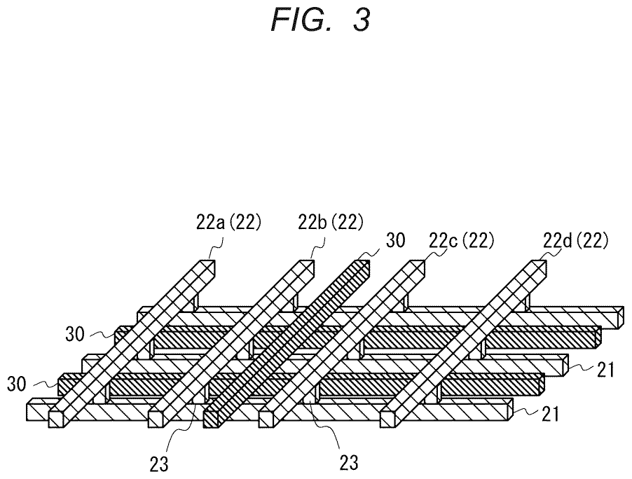

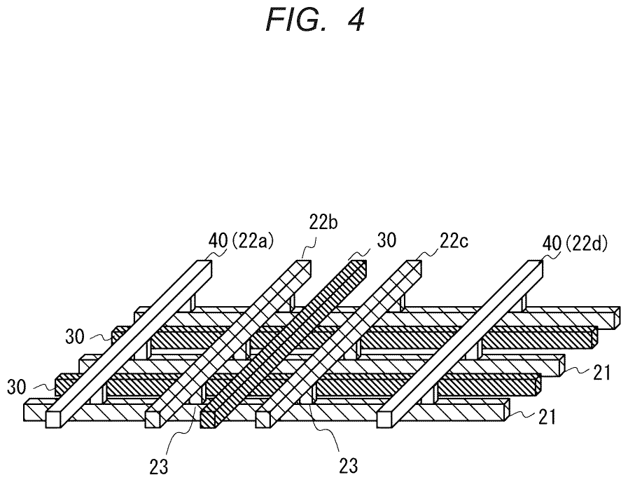

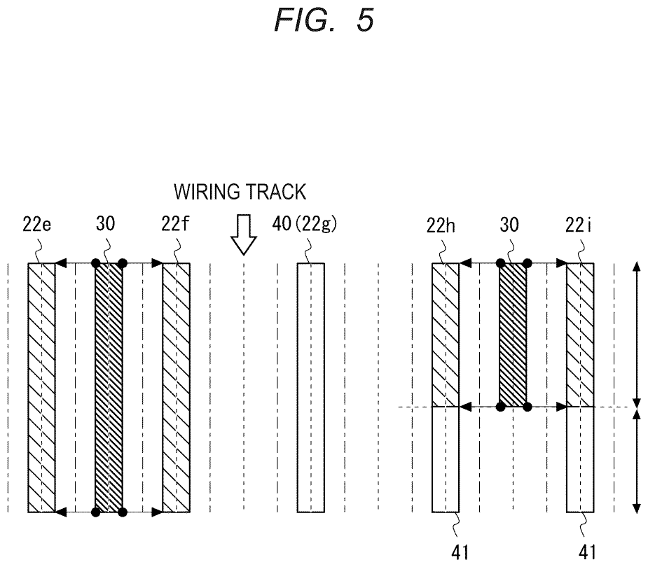

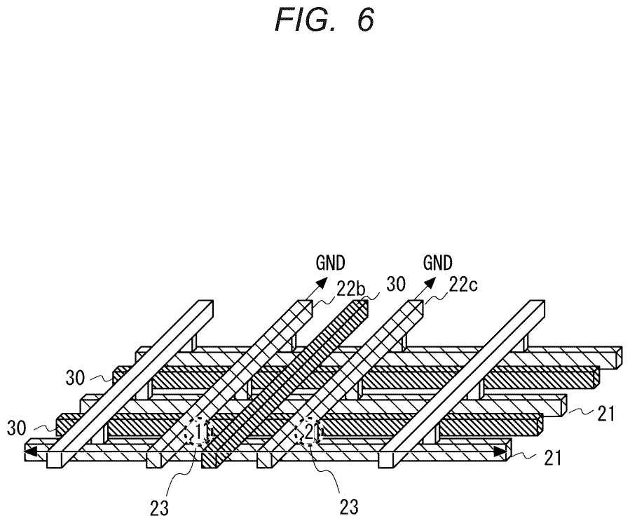

FIG. 1 is a diagram illustrating an exemplary wiring processing device of a semiconductor circuit device according to an embodiment. FIG. 2 is a diagram illustrating an example of shield wiring candidates. FIG. 3 is a diagram illustrating a state in which a shield target wiring is wired to a wiring track between shield wiring candidates in FIG. 2. FIG. 4 is a diagram for explaining a process of removing shield wiring candidates. FIG. 5 is a diagram for explaining a process of removing shield wiring candidates. FIG. 6 is a diagram for explaining a process of deleting vias between crossing shield wiring candidates. In the following description, an example in which the shield target wiring is a clock wiring, and the shield wiring is a ground mesh will be described.

The wiring processing device 10 performs a process of automatically determining wiring paths of multilayer wiring for clock wirings and shield wirings of a semiconductor circuit device. As illustrated in FIG. 1, the wiring processing device 10 includes a processing unit 11, a storage unit 12, a memory 13, and an input/output unit 14. The storage unit 12 is a storage device such as a hard disk or a flash memory. The storage unit 12 stores library information, various kinds of information obtained by circuit design in advance, and a wiring program according to the embodiment.

The library information includes information used in circuit design, such as block graphic information and terminal graphic information for primitive blocks such as flip-flops and macroblocks such as multipliers. The various kinds of information obtained by the circuit design include a netlist (inter-terminal connection information, wiring width information), underlying information (wiring track spacing, number of wiring layers, and the like), wiring prohibition information, and the like. The memory 13 is a volatile storage device such as a RAM, and is a storage area for temporarily storing data when the processing unit 11 operates.

The processing unit 11 is a processor that controls the components of the wiring processing device 10. The processing unit 11 reads a program from the storage unit 12, stores the program into the memory 13, and executes the program. Thus, the processing unit 11 operates the functions of the shield wiring candidate arrangement unit 111, the shield target arrangement unit 112 and the removing unit 113, and executes the automatic wiring processing according to the embodiment. The input/output unit 14 may include a display device such as a screen, and an input device such as a keyboard and a mouse. The display device displays a detailed wiring diagram or the like generated by the processing unit 11.

The respective components of the wiring processing device 10 may be realized by dedicated hardware. In addition, some or all of the components may be realized by a general-purpose or dedicated circuit, a processor, or the like, or a combination thereof. Part or all of the components of the device may be realized by a combination of the above-described circuitry and programs. Further, as the processor, a CPU (Central Processing Unit), GPU (Graphics Processing Unit), FPGA (Field-Programmable Gate Array), a quantum processor, or the like may be used.

The shield wiring candidate arrangement unit 111 performs processing of arranging a plurality of shield wiring candidates apart from each other. The shield wiring candidates adjacent to each other are arranged apart by a space for a wiring track necessary for arranging the shield target wiring. The shield wiring candidate may be a ground mesh or a power supply mesh. In the embodiment, the number of wiring tracks necessary for arranging one clock wiring is set to 1, and a ground mesh having a space for one wiring track in advance is arranged as a shield wiring candidate.

As illustrated in FIG. 2, the ground mesh 20 serving as a shield wiring candidate includes a first shield wiring candidate 21, a second shield wiring candidate 22, and a via 23. In the example illustrated in FIG. 2, the ground mesh 20 has a two-layer structure in which a lower layer is a first layer and an upper layer is a second layer.

A direction in which the first shield wiring candidate 21 extends is referred to as a first direction, and a direction in which the second shield wiring candidate 22 extends is referred to as a second direction. The first direction and the second direction are substantially orthogonal to each other. The plurality of first shield wiring candidates 21 are arranged in the first layer and extend in the first direction. The plurality of first shield wiring candidates 21 are arranged on the wiring tracks so as to be aligned in the second direction. The plurality of first shield wiring candidates 21 are arranged apart from each other. The first shield wiring candidates 21 adjacent to each other are arranged apart by a space for the wiring track necessary for arranging the clock wiring.

The plurality of second shield wiring candidates 22 are arranged in a second layer different from the first layer and extend in a second direction orthogonal to the first direction. The plurality of second shield wiring candidates 22 are arranged on the wiring tracks so as to be aligned in the first direction. The plurality of second shield wiring candidates 22 are arranged apart from each other. The second shield wiring candidates 22 adjacent to each other are arranged apart by a space for the wiring track necessary for arranging the clock wiring. The vias 23 are arranged at positions where the first shield wiring candidate 21 and the second shield wiring candidate 22 intersect with each other. The vias 23 electrically connect the first shield wiring candidate 21 and the second shield wiring candidate 22.

The second shield wiring candidates 22 arranged in the second layer as the upper layer are coupled to GND source. Note that the structure of the ground mesh 20 is not limited to this, and may be a laminated mesh structure of three or more layers. In the adjacent wiring layers, the shield wiring candidates are orthogonal to each other. With such a configuration, for example, in the case of multilayer wiring structure having three layers, the shield wiring candidates of the first layer and the shield wiring candidates of the third layer are parallel to each other, and the shield wiring candidates of the second layer can be arranged so as to be orthogonal to the shield wiring candidates of the first layer and the shield wiring candidates of the third layer. Also, the uppermost shield wiring candidates may be coupled to GND source.

The shield target arrangement unit 112 performs processing of arranging the shield target wiring on at least one of the plurality of wiring tracks provided between the plurality of shield wiring candidates. In the example shown in FIG. 3, in the first layer, the clock wirings 30 are arranged between the adjacent first shield wiring candidates 21.

Hereinafter, when distinguishing the four second shielded wire candidates 22, reference 22a, 22b, 22c, 22d are given from the left side of the drawing. In the second layer, among the four second shield wiring candidates 22, one clock wiring 30 is arranged between the second shield wiring candidates 22b, 22c. As described above, the clock wirings 30 are arranged using the wiring tracks in the ground mesh 20.

The removing unit 113 performs a process of removing shield wiring candidate that does not contribute to the arranged shield target wiring as shield wiring. The process of removing the shield wiring candidate that does not contribute to the arranged shield target wiring as the shield wiring will be described in detail with reference to FIGS. 4 and 5. This removing process includes two examples.

### First Example

First, the removing unit 113 searches for whether or not there is a shield target wiring on a wiring track adjacent to a shield wiring candidate. Then, the removing unit 113 removes the shield wiring candidate which is adjacent to the wiring track on which the shield target wiring is not arranged.

As shown in FIG. 4, in the first layer, the clock wirings 30 are arranged between the three first shield wiring candidates 21. In addition, in the second layer, the clock line 30 is arranged on the wiring track between the two second shield wiring candidates 22b, 22c.

On the other hand, the clock wiring 30 to be shielded does not exist on the wiring tracks adjacent to the two second shield wiring candidates 22a, 22d other than the second shield wiring candidates 22b, 22c. Thus, the second shield wiring candidates 22a, 22d, which is adjacent to the wiring track on which the clock wirings 30 are not arranged, becomes remove target wirings 40.

FIG. 5 is a view of the second shield wiring candidates 22 arranged in the second layers in plan view. Note that FIG. 5 is a diagram provided to explain a target of removing of shield wiring candidates and does not correspond to the configuration shown in FIG. 4. In FIG. 5, it is assumed that five second shield wiring candidates 22 are provided. These second shield wiring candidates 22 are distinguished and referred to as second shield wiring candidates 22e, 22f, 22g, 22h, 22i. Dotted lines, as indicated by an arrow in FIG. 5, are wiring tracks.

The clock wiring 30 is arranged on the wiring track between the second shield wiring candidates 22e, 22f. In this situation, the removing unit 113 determines that the shield target exists in the adjacent wiring track of the second shield wiring candidates 22e, 22f. These second shield wiring candidates 22e, 22f serve as the wiring to be left.

On the other hand, no clock wirings 30 is arranged in the adjacent wiring tracks on both sides of the second shield wiring candidate 22g. In this situation, the removing unit 113 determines that the shield target does not exist in the adjacent wiring tracks of the second shield wiring candidate 22g. The second shield wiring candidate 22g serve as the remove target wiring 40.

### Second Example

The removing unit 113 can remove only a part of the shield wiring candidate. Specifically, the shield target wiring is arranged on a part of the wiring track adjacent to the shield wiring candidate. The part of the wiring track is referred as first part of the wiring track. On the other part of the wiring track adjacent to the shield wiring candidate, no shield target wiring is arranged. The other part of the wiring track is referred as second part of the wiring track. The removing unit 113 performs a process of removing a part of the shield wiring candidate adjacent to the second part of wiring track.

As shown in FIG. 5, the clock wiring 30 is arranged on a part of the wiring track between the second shield wiring candidates 22h, 22i. In this case, the removing unit 113 determines that the shield target is present in a part of the second shield wiring candidates 22h, 22i adjacent to the clock wiring 30, and determines that the shielding target is not present in the other part of the second shield wiring candidate 22h, 22i that is not adjacent to the clock wiring 30.

Therefore, the part of the second shield wiring candidates 22h, 22i adjacent to the clock wiring 30 is to be left. On the other hand, the other part of the second shield wiring candidates 22h, 22i not adjacent to the clock wiring 30 becomes a remove target wiring part 41.

The removing unit 113 removes the remove target wiring 40 and the remove target wiring part 41, leaving the second shield wiring candidate 22 determined to be left in the first example and/or the second example. As a result, the shield wiring candidate that does not contribute as the shield wiring for the clock wiring 30 is removed.

Referring to FIG. 6, since the second shield wiring candidates 22b, 22c remains as the shield wiring, there are two GND supply points to one first shield wiring candidate 21. For example, the first shield wiring candidate 21 at the front side of FIG. 6 is supplied with GND potentials from the second shield wiring candidates 22b, 22c via two vias 23 (in FIG. 6, via numbers (1) and (2) are shown). However, the presence of two or more vias can cause current to flow and violate EM (electromigration).

Therefore, the removing unit 113 removes such redundant vias. When there are a plurality of second shield candidate wirings that intersect the first shield wiring candidate that contributes as the shield wiring, the removing unit 113 removes the other vias while leaving one via among the plurality of vias that connect between the first shield wiring candidate that contributes as the shield wiring and the second shield wiring that contributes as the shield wiring.

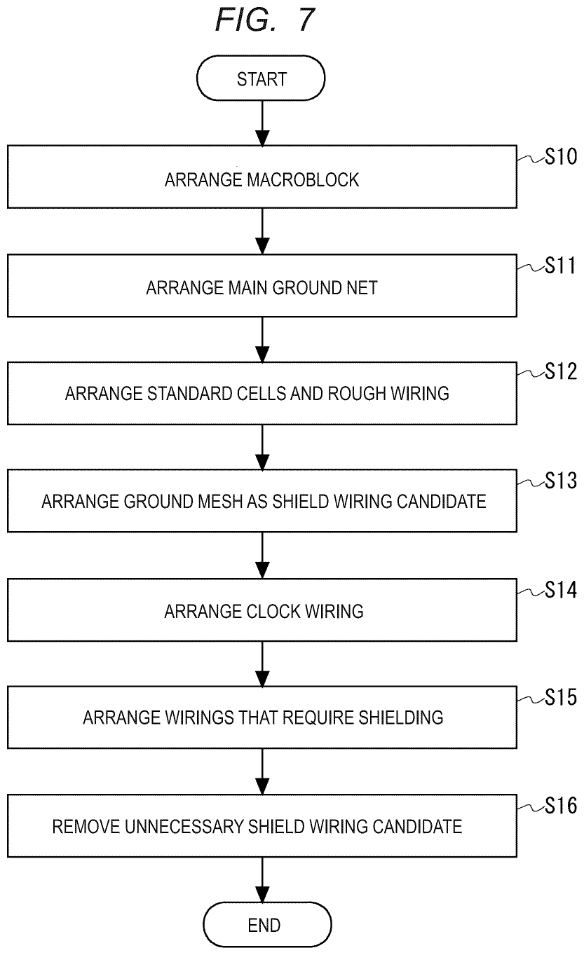

Next, a wiring method of the semiconductor circuit device according to the embodiment will be described with reference to FIG. 7. FIG. 7 is a flowchart illustrating an example of a wiring method of the semiconductor circuit device according to the embodiment. The circuit designer performs circuit design by CAD using the library data of the storage unit 12. Then, the circuit designer generates various kinds of information such as a netlist for an internal region set in the semiconductor chip as a wiring target region. The various kinds of information include a netlist, underlying information, and wiring prohibition information. These various kinds of information may be collectively referred to as a netlist or the like. The generated netlist or the like is stored in the storage unit 12.

As illustrated in FIG. 7, the wiring processing device 10 first performs macroblock arrangement (step S10) and main ground net arrangement (step S11) in the internal region of a semiconductor chip using a netlist or the like. Although not illustrated here, the arrangement of the main power supply net, the primitive blocks, and the like may also be performed. The macroblock is partial circuit information of a functional block unit used in layout design of a semiconductor circuit device. The main ground net and the main power supply net are wirings for power supply such as transistors.

Here, the main ground net and the main power supply net are power supply wirings having a larger current capacity than the ground mesh and the power supply mesh. The wiring width and the wiring interval of the main ground net and the main power supply net are larger than those of the ground mesh and the power supply mesh. Further, since a current flows through the main ground net and the main power supply net, the vias larger than the ground mesh and the power supply mesh are formed.

Then, the wiring processing device 10 arranges the standard cells and performs rough wiring (step S12). The standard cell is a standard function block prepared in advance and can be stored in the storage unit 12 as library information. After the standard cells are arranged, the rough wiring is performed to confirm local wiring congestion.

Then, the wiring processing device 10 arranges a ground mesh serving as a shield wiring candidate on substantially the entire surface of the semiconductor chip (step S13). As described above, in the embodiment, a plurality of first shield wiring candidates 21 having a linear shape are arranged in the first direction in the first layer. The interval between the adjacent first shield wiring candidates 21 is a space for the wiring track required for arranging the clock wiring 30. Further, in the second layer adjacent to the first layer, a plurality of second shield wiring candidates 22 having a linear shape are arranged in the second direction orthogonal to the first direction. The interval between the adjacent second shield wiring candidates 22 is a space for the wiring track for arranging the clock wiring 30.

The respective layers are connected to each other by vias provided in the interlayer insulating film. The shield wiring candidate that does not contribute to the shield wiring is removed in a later step. In the embodiment, a ground mesh is generated in distinction from the main ground net.

Thereafter, the wiring processing device 10 arranges the clock wiring 30 for supplying a clock signal to each unit (step S14). The clock wiring 30 is arranged in at least one of the plurality of wiring tracks each provided between the plurality of shield wiring candidates.

After the clock wiring 30 is arranged, the wiring processing device 10 performs timing optimization of the clock and arranges wirings to be shielded in addition to the clock wirings 30 referring to a netlist or the like. The wirings to be shielded in addition to the clock wirings 30 comprise some of detailed wiring between all the standard cells (step S15). The wirings to be shielded may also be arranged in at least one of the plurality of wiring tracks provided between the plurality of shield wiring candidates. The wirings to be shielded other than the clock wiring 30 comprise a wiring interference with another wiring or a wiring that needs to be prevented from interfering with another wiring.

That is, in the embodiment, for the wirings to be shielded, such as clock wiring 30, an ideal path with the shield wiring candidates on both sides thereof is selected. The arrangement location and the wiring path of each component in the internal region of the semiconductor chip can be stored in the memory 13 as layout information.

Then, the wiring processing device 10 removes unnecessary shield wiring candidates that do not contribute to the arranged shield target wiring (step S16). Specifically, the wiring processing device 10 searches for whether or not there is a shield target wiring on a wiring track adjacent to the shield wiring candidate, and adds a holding setting to the shield wiring candidate adjacent to the shield target wiring.

In addition, when there is a shield target wiring on a part of the wiring track adjacent to the shield wiring candidate, the wiring processing device 10 divides the pattern of the shield wiring candidate and adds a holding setting to the part contributing as the shield wiring. Then, the wiring processing device 10 removes the shield wiring candidates other than the shield target candidates which the holding setting are added. The wiring processing device 10 removes the other part shield wiring candidate other than the part of the shield target candidate which the holding setting is added. The wiring processing device 10 can determine, for example, a portion to be removed from the shielded wiring candidate based on the coordinates of the clock wiring 30.

Removing of unnecessary shield wiring candidates may include removing of the above-described redundant vias. As an example, the wiring processing device 10 detects, from the first shield wiring candidate 21 arranged in the lower layer, the number of vias 23 connected to the second shield wiring candidate 22 left as the shield wiring in the upper layer. If more than one vias 23 are present, the wiring processing device 10 removes the via(s) 23 leaving any one of the vias 23.

For example, the wiring processing device 10 can count, in FIG. 6, the number of vias 23 connecting the respective first shield wiring candidates 21 to the second shield wiring candidates 22 left as the shield wiring of the upper layer from the left side to the right side. In the example shown in FIG. 6, since there are two vias 23, the wiring processing device 10 can remove the via 23 of the right-hand via number (2) leaving the via 23 of the first detected left-hand via number (1).

After S16 of steps, the detailed wiring including the signal wirings between the remaining standard cells is performed, whereby the wiring process of the semiconductor circuit device according to the embodiment is completed (not shown in FIG. 7).

As described above, according to the embodiment the ground mesh 20 made of the shield wiring candidates is formed in distinction from the main ground net for supplying GND. Because the main ground net has a wiring interval that is too large for the clock wiring and cannot contribute the shield wiring for clock wirings. By arranging the clock wirings 30 using the wiring tracks of the ground mesh 20, it is possible to ensure the degree of freedom in arranging the clock wirings 30 and select an ideal wiring path.

In addition, since shield wiring candidates serving as shield wiring are arranged at positions adjacent to the wiring to be shield, such as the clock wiring 30, it is possible to improve the shield wiring coverage ratio with respect to the shield target wiring.

Further, as compared with an example in which the shield wiring is arranged after the clock wiring is arranged without preparing the shield wiring candidate in advance, in the embodiment, it is possible to reduce the waste that unnecessary shield wiring is arranged on top of each other. It is expected that the semiconductor circuit device is miniaturized, and the degree of integration is improved. Further, it is possible to avoid unnecessary shield wiring processing, it is also possible to speed up the wiring processing.

Although the invention made by the present inventor has been specifically described based on the embodiment, the present invention is not limited to the embodiment described above, and it is needless to say that various modifications can be made without departing from the gist thereof. For example, the present invention is applicable not only to a semiconductor chip but also to a printed circuit board. Further, the shield wiring is not necessarily required to be on both sides of the shield target wiring, and the shield wiring on one side may be omitted as necessary.

Each functional block that performs the various processes described in the drawings may be configured by a processor, a memory, or other circuits in hardware. Further, the above-described processing can be realized by causing a processor to execute a program. Accordingly, these functional blocks may be implemented in various forms by hardware only, software only, or a combination thereof, and are not limited to any one.

Also, the programs described above may be stored and provided to a computer using various types of non-transitory computer readable media. Non-transitory computer readable media includes various types of tangible storage media. Exemplary non-transitory computer-readable media include solid-state memories (e.g., masked ROM, PROM (Programmable ROM), EPROM (Erasable PROM, flash ROM, RAM, etc. The programs may also be supplied to the computer by various types of transitory computer-readable transitory computer readable media. Examples of transitory computer-readable media include electrical signals, optical signals, and electromagnetic waves. The transitory computer readable medium may provide the program to the computer via wired or wireless communication paths, such as electrical wires and optical fibers.

What is claimed is:

1. A wiring method of a semiconductor circuit device that is executed by a computer, the wiring method comprising:
arranging a plurality of shield wiring candidates such that the plurality of shield wiring candidates adjacent to each other are arranged apart by a space for a wiring track;
arranging a shield target wiring on at least one of wiring tracks between the plurality of shield wiring candidates adjacent to each other; and
removing a shield wiring candidate which do not contribute as shield wiring to the shield target wiring arranged.

2. The wiring method according to claim 1,
wherein the removing step comprises:
searching whether the shield target wiring is arranged on the wiring track adjacent to one of the plurality of shield wiring candidates, and
removing the one of the plurality of shield wiring candidates that is not adjacent to the wiring track on which the shield target wiring is arranged.

3. The wiring method according to claim 2,
wherein, the one of the plurality of shield wiring candidates include a first part and a second part,
wherein, if the first part of the one of the plurality of shield wiring candidates is adjacent to a wiring track on which the shield target wiring is arranged and the second part of the one of the plurality of shield wiring candidates is adjacent to the wiring track on which the shield target wiring is not arranged, the second part of the one of the plurality of shield target wiring is removed in the removing step.

4. The wiring method according to claim 1,
wherein the plurality of shield wiring candidates include a plurality of first shield wiring candidates and a plurality of second shield wiring candidates,
wherein the plurality of first shield wiring candidates are arranged in a first layer and extend to a first direction, and
wherein the plurality of second shield wiring candidates are arranged in a second layer that is different from the first layer, extend to a second direction that is orthogonal to the first direction, and electrically coupled to the plurality of first shield wiring candidates through a plurality of vias which are provided at points where the plurality of second shield wiring candidates intersect the plurality of first shield wiring candidates in plan view.

5. The wiring method according to claim 4,
wherein, when there are a plurality of points between the first shield wiring candidate which contribute as shield wiring and the second shield wiring candidate contribute as shield wiring intersect, the removing step further comprises leaving one of the plurality of vias to be provided at one of the plurality of points and removing the other of the plurality of vias to be provided at the other of plurality points.

6. The wiring method according to claim 1,
wherein the plurality of shield wiring candidates is functioned as ground mesh or power supply mesh.

7. The wiring method according to claim 1,
wherein the shield target wiring comprises a clock wiring.

8. A non-transitory computer readable medium storing a wiring program of a semiconductor circuit device executable processes by a computer, the processes comprising:
arranging a plurality of shield wiring candidates such that the plurality of shield wiring candidates adjacent to each other are arranged apart by a space for a wiring track;
arranging a shield target wiring on at least one of wiring tracks between the plurality of shield wiring candidates adjacent to each other; and
removing a shield wiring candidate which do not contribute as shield wiring to the shield target wiring arranged.

9. The non-transitory computer readable medium according to claim 8,
wherein the removing process comprises:
searching whether the shield target wiring is arranged on the wiring track adjacent to one of the plurality of shield wiring candidates, and
removing the one of the plurality of shield wiring candidates that is not adjacent to the wiring track on which the shield target wiring is arranged.

10. The non-transitory computer readable medium according to claim 9,
wherein, when the one of the plurality of shield wiring candidates include a first part and a second part, the first part of the one of the plurality of shield wiring candidates is adjacent to a wiring track on which the shield target wiring is arranged and the second part of the one of the plurality of shield wiring candidates is adjacent to the wiring track on which the shield target wiring is not arranged, the removing process further comprises:
removing the second part of the one of the plurality of shield target wiring,

11. The non-transitory computer readable medium according to claim 8,
wherein the plurality of shield wiring candidates include a plurality of first shield wiring candidates and a plurality of second shield wiring candidates,
wherein the plurality of first shield wiring candidates are arranged in a first layer and extend to a first direction, and
wherein the plurality of second shield wiring candidates are arranged in a second layer that is different from the first layer, extend to a second direction that is orthogonal to the first direction, and electrically coupled to the plurality of first shield wiring candidates through a plurality of vias which are provided at points where the plurality of second shield wiring candidates intersect the plurality of first shield wiring candidates in plan view.

12. The non-transitory computer readable medium according to claim 8,
wherein the removing process further comprises:
leaving one of the plurality of vias and removing the other of the plurality of vias.

13. The non-transitory computer readable medium according to claim 8,
wherein the plurality of shield wiring candidates is functioned as ground mesh or power supply mesh.

14. A wiring processing device for semiconductor circuit device, comprising:
a shield wiring candidate arrangement unit configured to arrange a plurality of shield wiring candidates such that the plurality of shield wiring candidates adjacent to each other are arranged apart by a space for a wiring track;
a shield target arrangement unit configured to arrange a shield target wiring on at least one of wiring tracks between the plurality of shield wiring candidates adjacent to each other; and
a removing unit configured to a shield wiring candidate which do not contribute as shield wiring to the shield target wiring arranged.

15. The wiring processing device according to claim 14,
wherein the removing unit is configured to search whether the shield target wiring is arranged on the wiring track adjacent to one of the plurality of shield wiring candidates, and remove the one of the plurality of shield wiring candidates that is not adjacent to the wiring track on which the shield target wiring is arranged.

16. The wiring processing device according to claim 15,
wherein, when the one of the plurality of shield wiring candidates include a first part and a second part, the first part of the one of the plurality of shield wiring candidates is adjacent to a wiring track on which the shield target wiring is arranged and the second part of the one of the plurality of shield wiring candidates is adjacent to the wiring track on which the shield target wiring is not arranged, the removing unit is configured to remove the second part of the one of the plurality of shield target wiring.

17. The wiring processing device according to claim 14,
wherein the plurality of shield wiring candidates include a plurality of first shield wiring candidates and a plurality of second shield wiring candidates,
wherein the plurality of first shield wiring candidates are arranged in a first layer and extend to a first direction, and
wherein the plurality of second shield wiring candidates are arranged in a second layer that is different from the first layer, extend to a second direction that is orthogonal to the first direction, and electrically coupled to the plurality of first shield wiring candidates through a plurality of vias which are provided at points where the plurality of second shield wiring candidates intersect the plurality of first shield wiring candidates in plan view.

18. The wiring processing device according to claim 18,
wherein, when there are a plurality of points between the first shield wiring candidate which contribute as shield wiring and the second shield wiring candidate contribute as shield wiring intersect, the removing unit is configured to leave one of the plurality of vias to be provided at one of the plurality of points and remove the other of the plurality of vias to be provided at the other of plurality points.

19. The wiring processing device according to claim 14,
wherein the plurality of shield wiring candidates is functioned as ground mesh or power supply mesh.

20. The wiring processing device according to claim 14,
wherein the shield target wiring comprises a clock wiring.
